(19) United States
(12) Patent Application Publication
(10) Pub. No.: US 2025/0056167 A1
(43) Pub. Date: Feb. 13, 2025

(54) HEARING AID DEVICE WITH IMPROVED FEEDBACK SUPPRESSION AND A SUPPRESSION METHOD

(71) Applicant: EVOCO LABS CO., LTD., Shanghai (CN)

(72) Inventors: Linkai LI, Shanghai (CN); Ziwei CHEN, Shanghai (CN); Congxi LU, Shanghai (CN); Hongcheng SUN, Shanghai (CN)

(21) Appl. No.: 18/720,678

(22) PCT Filed: Dec. 16, 2022
(86) PCT No.: PCT/CN2022/139620

§ 371 Date: Jun. 17, 2024

(30) Foreign Application Priority Data
Dec. 17, 2021 (CN) 202111550488.1

(51) Int. Cl. H04R 25/00; H03F 3/183

(52) U.S. Cl. CPC H04R 25/453; H04R 25/505; H04R 25/604; H03F 3/183; H03F 2200/03; H04R 2225/41

(57) ABSTRACT

A hearing aid device at least partially disposed in an ear canal is provided. The hearing aid device comprises a sound blocking component constructed to be in contact with the ear canal to divide the ear canal into a far side away from an eardrum and an adjacent side close to the eardrum and block sound transmission between the far side away from the eardrum and the adjacent side close to the eardrum; an environmental sound microphone configured for receiving sound from the far side away from the eardrum and generating an environmental sound signal corresponding to the received sound; an auxiliary calibration microphone configured for receiving sound from the adjacent side close to the eardrum and generating an auxiliary calibration signal corresponding to the received sound; a processor configured to receive the environmental sound signal and the auxiliary calibration signal and generate a calibrated environmental sound signal based on the environmental sound signal and the auxiliary calibration signal; and a receiver configured to receive the calibrated environmental sound signal from the processor and convert the calibrated environmental sound signal into sound emitted to the adjacent side close to the eardrum.

### TECHNICAL FIELD

The present application generally relates to hearing aid devices, and more particularly, to a hearing aid device with improved feedback suppression and a method of feedback echo suppression.

### BACKGROUND OF THE INVENTION

Feedback Echo is one of the common problems with a hearing aid. Sound played by a receiver of the hearing aid is collected by a microphone after passing through a sound feedback path, which is played by the receiver again after being amplified, thereby forming a positive feedback mechanism. This positive feedback mechanism will continuously amplify the sound, resulting in echo and whistling phenomena. The whistling phenomenon not only affects the effect of the hearing aid, but also limits a gain range that the hearing aid can output. The more severe the whistling phenomenon is, the higher degree of limitation an output volume of the hearing aid is limited to, which leads to an insufficient achievement of gain compensation of the hearing aid which is required by users.

With the development of technology, some whistling suppression algorithms have been used to reduce the occurrence of the whistling phenomena. For most users with mild or moderate hearing loss, these algorithms have basically solved the whistling problem. However, for users with moderate to severe hearing loss, they have higher requirements for gain of the hearing aid, and the current whistling suppression algorithms can not effectively suppress the occurrence of the whistling phenomena. This affects user experience of the users with moderate to severe hearing loss.

Therefore, a need exists for an improved hearing aid to solve the whistling problem.

### SUMMARY OF THE INVENTION

An objective of the present application is to provide a hearing aid device with improved feedback suppression and a feedback suppression method, which efficiently solves the whistling problem resulted from positive feedback of the echo.

According to an aspect of the present application, a hearing aid device at least partially disposed in an ear canal is provided. The hearing aid device comprises a sound blocking component constructed to be in contact with the ear canal to divide the ear canal into a far side away from an eardrum and an adjacent side close to the eardrum and block sound transmission between the far side away from the eardrum and the adjacent side close to the eardrum; an environmental sound microphone configured for receiving sound from the far side away from the eardrum and generating an environmental sound signal corresponding to the received sound; an auxiliary calibration microphone configured for receiving sound from the adjacent side close to the eardrum and generating an auxiliary calibration signal corresponding to the received sound; a processor configured to receive the environmental sound signal and the auxiliary calibration signal and generate a calibrated environmental sound signal based on the environmental sound signal and the auxiliary calibration signal; and a receiver configured to receive the calibrated environmental sound signal from the processor and convert the calibrated environmental sound signal into sound emitted to the adjacent side close to the eardrum.

In some embodiments, the processor comprises a self-adaptive filter, and generating a calibrated environmental sound signal based on the environmental sound signal and the auxiliary calibration signal comprises: correcting the auxiliary calibration signal through the self-adaptive filter to obtain an estimated sound feedback signal of an echo feedback propagated from the receiver to the environmental sound microphone; subtracting the estimated sound feedback signal from the environmental sound signal to obtain the calibrated environmental sound signal.

In some embodiments, the processor comprises a signal amplifier, and the signal amplifier amplifies the calibrated environmental sound signal and sends the calibrated environmental sound signal to the receiver.

In some embodiments, the self-adaptive filter applies least mean square algorithm or normalized least mean square algorithm.

In some embodiments, the sound blocking component comprises a sound propagation channel for transmitting sound from the receiver to the eardrum, and the auxiliary calibration microphone is arranged to receive the sound propagated in the sound propagation channel from the receiver at least from one side of the sound propagation channel.

In some embodiments, a sound insulation component is arranged between the auxiliary calibration microphone and the sound propagation channel, and the sound insulation component is arranged to attenuate the sound transmission from the sound propagation channel to the auxiliary calibration microphone.

In some embodiments, at least a part of the auxiliary calibration microphone constitutes a sidewall of the sound propagation channel.

In some embodiments, an angle between an orientation of a sound receiving part of the auxiliary calibration microphone and a sound propagation direction towards the eardrum in the sound propagation channel is approximately 90 degrees.

In some embodiments, an angle between an orientation of a sound receiving part of the auxiliary calibration microphone and a sound propagation direction towards the eardrum in the sound propagation channel is less than 90 degrees.

In some embodiments, the hearing aid device further comprises a cavity substantially parallel to the sound propagation channel, the cavity is constructed to receive sound in the sound propagation channel, the auxiliary calibration microphone is arranged in the cavity, and an orientation of an sound receiving part of the auxiliary calibration microphone is substantially the same as a sound propagation direction towards the eardrum in the sound propagation channel.

In some embodiments, the cavity is further constructed to transmit sound propagated from the sound propagation channel to outside of the cavity.

In some embodiments, the sound blocking component comprises a sound propagation channel for transmitting sound from the receiver to the eardrum, the sound propagation channel has a sound propagation opening for transmitting sound towards the eardrum, and the auxiliary calibration microphone is arranged to receive sound emitted from the sound propagation opening.

In some embodiments, the environmental sound microphone is set such that when the hearing aid device is at least partially disposed in the ear canal, the environmental sound microphone is disposed at an entrance of the ear canal or in the ear canal.

In some embodiments, the auxiliary calibration microphone is configured to be adjacent to the receiver.

In some embodiments, the sound blocking component comprises an inner main body and an outer blocking part arranged substantially around the inner main body, and the sound propagation channel is formed within the inner main body.

In some embodiments, the receiver is a moving iron receiver.

In some embodiments, the hearing aid device further comprises a second environmental sound microphone, the second environmental sound microphone is set such that when the hearing aid device is at least partially disposed in the ear canal, the environmental sound microphone is in a position far away from the ear canal to receive sound from the far side away from the eardrum and generate a second environmental sound signal corresponding to the received sound.

In some embodiments, the second environmental sound microphone is configured for being arranged at an ear dorsum.

In some embodiments, the processor is further configured to receive the second environmental sound signal and generate a calibrated environmental sound signal based on the environmental sound signal, the auxiliary calibration signal, and the second environmental sound signal.

According to another aspect of the present application, a method for achieving sound feedback suppression using a hearing aid device at least partially disposed in an ear canal is provided. The hearing aid device comprises a sound blocking component, the sound blocking component is constructed to be in contact with the ear canal to divide the ear canal into a far side away from an eardrum and an adjacent side close to the eardrum and block sound transmission between the far side away from the eardrum and the adjacent side close to the eardrum. The method comprises: receiving sound from the far side away from the eardrum and generating an environmental sound signal corresponding to the received sound through an environmental sound microphone; receiving sound from the adjacent side close to the eardrum and generating an auxiliary calibration signal corresponding to the received sound through an auxiliary calibration microphone; generating a calibrated environmental sound signal based on the environmental sound signal and the auxiliary calibration signal.

In some embodiments, generating the calibrated environmental sound signal based on the environmental sound signal and the auxiliary calibration signal comprises: correcting the auxiliary calibration signal through a self-adaptive filter of the hearing aid device to obtain an estimated sound feedback signal of an echo feedback propagated from the receiver of the hearing aid device to the environmental sound microphone; subtracting the estimated sound feedback signal from the environmental sound signal to obtain the calibrated environmental sound signal.

In some embodiments, the hearing aid device further comprises a second environmental sound microphone, the second environmental sound microphone is set such that when the hearing aid device is at least partially disposed in the ear canal, the environmental sound microphone is in a position far from the ear canal, the method further comprises: receiving sound from the far side away from the eardrum and generating a second environmental sound signal corresponding to the received sound through the second environmental sound microphone; generating a calibrated environmental sound signal based on the environmental sound signal, the auxiliary calibration signal and the second environmental sound signal.

It is to be understood that the above is a summary of the present application, and may include simplification, summarization, and omission of details. Therefore, those skilled in the art should recognize that this section is exemplary and explanatory only, and are not restrictive of the invention. This summary is neither intended to determine essential or critical features of the claimed subject matter, nor is it intended to be used as an aid in determining a scope of the claimed subject matter.

### DESCRIPTION OF DRAWINGS

The above and other features of this application will be more sufficiently understood from the following detailed description and the claims in conjunction with the drawings. It should be understood that these drawings illustrate only some embodiments of the application, and therefore should not be considered as limitation of a scope of the application. With the drawings, the contents of the application will be described more clearly in detail.

FIG. 1 illustrates a schematic diagram of a hearing aid device 100 according to an embodiment of the present application.

FIG. 2 illustrates a schematic diagram of a hearing aid device 200 when worn in an ear canal according to another embodiment of the present application.

FIG. 3 illustrates a perspective schematic diagram of an inner main body 312 of a hearing aid device according to another embodiment of the present application.

FIGS. 4, 5 and 6 illustrate cross-sectional schematic diagrams of different positions of the auxiliary calibration microphone relative to the sound propagation channel, respectively, in the inner main body 312 shown in FIG. 3 according to different embodiments.

FIG. 7 illustrates a flow chart of a sound feedback suppression method using the hearing aid device 100 shown in FIG. 1.

FIG. 8 illustrates a schematic diagram of a feedback suppression algorithm used in a hearing aid device according to an embodiment of the present application.

FIG. 9 illustrates a flow chart of a sound feedback suppression method using a hearing aid device according to another embodiment of the present application.

FIG. 10 illustrates a schematic diagram of a feedback suppression algorithm used in a hearing aid device according to another embodiment of the present application.

FIG. 11 illustrates a graph of HASQI with the change of gain levels without using a feedback suppression algorithm, using a feedback suppression algorithm of an embodiment of the present application, and using a traditional feedback suppression algorithm.

### DETAILED DESCRIPTION OF THE INVENTION

The following detailed description refers to the accompanying drawings that form a part hereof. In the drawings, similar reference labels typically represent similar components, unless dictated otherwise in context. The exemplary embodiments described in the detailed description, the drawings, and the claims are not limiting. Other embodiments may be utilized, and other changes may be made, without departing from the spirit or scope of the subject matter presented here. It can be understood that various different configurations, substitutions, combinations, designs of the aspects of the subject matter described generally and illustrated in the drawings of the present application can be made, and all of which clearly constitute a part of the subject matter of the present application.

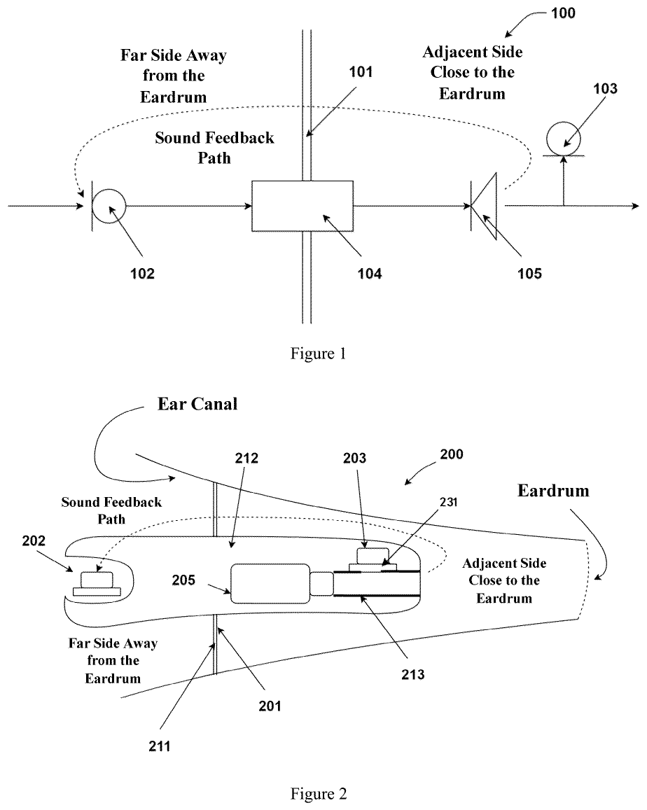

FIG. 1 illustrates a schematic diagram of a hearing aid device 100 according to an embodiment of the present application. In practical application, the hearing aid device 100 is at least partially disposed in a user's ear canal to assist the user to enhance hearing. For example, part of physical structures of the hearing aid device 100 is accommodated in the user's ear canal, while another part of the structures extends outwards from the user's ear canal; or, an entire structure of the hearing aid device 100 is accommodated within the user's ear canal. In some embodiments, the hearing aid device 100 can be disposed only in the user's left or right ear; and in other embodiments, the hearing aid device 100 can work in conjunction with another hearing aid device. The hearing aid device 100 and the another hearing aid device are disposed in the user's left and right ears, respectively.

As shown in FIG. 1, the hearing aid device 100 includes a sound blocking component 101. In some embodiments, the sound blocking component 101 is constructed to be in contact with an inner contour of the ear canal to divide the ear canal into two regions, that is, a far side away from an eardrum and an adjacent side close to the eardrum, and to block or at least attenuate sound propagation between the far side away from the eardrum (i.e., the relative outer side) and the adjacent side close to the eardrum (i.e., the relative inner side). The sound blocking component 101 has a cross-sectional contour that is the same as or similar to that of the ear canal, such that when the user wears the hearing aid device 100, it maintains in contact with an inner contour of the user's ear canal. In some embodiments, the sound blocking component 101 is at least partially made of a sound insulation material such that when it is worn into the patient's ear canal, it can better block the sound propagation between the far side away from the eardrum and the adjacent side close to the eardrum. In other embodiments, the contacting part of the sound blocking component 101 with the inner contour of the ear canal comprises a flexible material (such as a sponge or a silicone material) such that it can adaptively change its shape according to its position in the ear canal and a contacting situation, thus fitting with the inner contour of the ear canal to achieve a better sound insulation effect.

It should be noted that the sound blocking component 101 shown in FIG. 1 is only an exemplary representation, and in some alternative embodiments, it can be any structure or shape that can be arranged in the ear canal, divide the ear canal, and block the sound propagation. In some embodiments, the sound blocking component 101 can be an integrated component, while in some other embodiments, it can be composed of multiple parts. For example, the sound blocking component may include an inner main body and an outer blocking part arranged substantially around the inner main body. The inner main body can be a shell for loading various components, while the outer blocking part can be a flexible blocking rubber ring or other flexible structures substantially arranged around the shell.

The hearing aid device 100 also includes an environmental sound microphone 102 located on an outer side of the sound blocking component 101, which is configured to receive sound from the far side away from the eardrum and to generate an environmental sound signal corresponding to the received sound. It can be understood that the environmental sound signal includes external sound generated within the user's environment, and may also include sound emitted by the user himself. It should be noted that the “receive sound from the far side away from the eardrum” mentioned here includes any construction or arrangement that the environmental sound microphone 102 can be configured to collect sound from the far side away from the eardrum when the hearing aid device 100 is worn in the ear canal. In some embodiments, the environmental sound microphone 102 can be disposed within the sound blocking component 101, for example, embedded within the sound blocking component 101, while its sound receiving part is at least partially oriented and exposed to an external space of the far side away from the eardrum. In some other embodiments, the environmental sound microphone 102 can also be arranged on a side surface of the sound blocking component 101 which is away from the eardrum. In some other embodiments, the environmental sound microphone 102 may be arranged at a side of the sound blocking component 101 which is away from the eardrum, and it may not be in direct contact with the sound blocking component 101. For example, as shown in FIG. 1, there is a certain distance between the environmental sound microphone 102 and the sound blocking component. In addition, in some embodiments, when the hearing aid device 100 is worn, the environmental sound microphone 102 can be located at an entrance of the ear canal or a certain position in the ear canal, thereby reducing the transmission delay of the environmental sound signal. In some other embodiments, the environmental sound microphone 102 can also be arranged outside the ear canal.

The hearing aid device 100 further includes an auxiliary calibration microphone 103 located on an inner side of the sound blocking component 101, which is configured to receive sound from the adjacent side close to the eardrum and to generate an auxiliary calibration signal corresponding to the received sound. Similar to the description of the environmental sound microphone above, the “receive sound from the adjacent side close to the eardrum” mentioned here includes any construction or arrangement that the auxiliary calibration microphone 103 can be configured to receive sound from the adjacent side close to the eardrum when the hearing aid device 100 is worn in the ear canal. In some embodiments, the auxiliary calibration microphone 103 can be set within the sound blocking component 101, while its sound receiving part is at least partially oriented and exposed to the space of the adjacent side close to the eardrum. In some other embodiments, the auxiliary calibration microphone 103 may be located on a side surface of the sound blocking component 101 which is adjacent to the eardrum. In some other embodiments, the auxiliary calibration microphone 103 may be located at a side of the sound blocking component 101 which is adjacent to the eardrum, and it may not be in direct contact with the sound blocking component 101.

The hearing aid device 100 further includes a processor 104 (the position of the processor 104 shown in FIG. 1 is exemplary only) and a receiver 105. The processor 104 is configured to be communicationally coupled with the environmental sound microphone 102 and the auxiliary calibration microphone 103, to receive the environmental sound signal and the auxiliary calibration signal. Based on the received environmental sound signal and the received auxiliary calibration signal, the processor 104 may calculate and generate a calibrated environmental sound signal, thereby effectively suppressing echo feedback and preventing an occurrence of whistling. A specific method or algorithm for feedback suppression based on the environmental sound signal and the auxiliary calibration signal will be described in detail below. The receiver 105 is communicationally coupled with the processor 104, which can receive the calibrated environmental sound signal from the processor 104 and convert the calibrated environmental sound signal into sound emitted to the adjacent side close to the eardrum. The receiver 105 can adopt various suitable constructions and settings, such as a moving iron receiver, a moving coil receiver, a coil iron receiver, or an electrostatic receiver, or any combination of the above items. In some embodiments, the receiver 105 can be set on the side surface of the sound blocking component 101 which is adjacent to the eardrum. In some other embodiments, the receiver 105 can be set within the sound blocking component 101, while its sounding part is at least partially exposed to the space of the adjacent side close to the eardrum. In some other embodiments, the receiver 105 is located at the side of the sound blocking component 101 which is adjacent to the eardrum but may not be in direct contact with the sound blocking component 101. As shown in FIG. 1, the auxiliary calibration microphone 103 is configured to be adjacent to the receiver 105 to better receive the sound emitted by the receiver 105, convert the sound into an auxiliary calibration signal, and send it to the processor 104.

Still referring to FIG. 1, although the sound blocking component 101 may block or attenuate the sound from the adjacent side close to the eardrum to the far side away from the eardrum, in actual use, a part of the sound emitted by the receiver 105 may still pass through a sound feedback path to reach the environmental sound microphone 102 located at the far side away from the eardrum. If this part of the sound is left untreated, the sound feedback may still cause the whistling.

To solve the whistling problem, in the above embodiment, the auxiliary calibration signal collected by the auxiliary calibration microphone 103 is used for auxiliary correction. Specifically, the inventors of the present application found that the auxiliary calibration signal not only includes sound directly played by the receiver 105, but also includes reverberation generated after the sound emitted by the receiver 105 is reflected in the ear canal. The auxiliary calibration signal is then sent to the processor 104 such that it can serve as a reference signal to determine an estimated sound feedback signal of actual feedback echo, and the actual feedback echo is the signal transmitted to the environmental sound microphone 102 through the sound feedback path. Subsequently, by subtracting the estimated sound feedback signal from the environmental sound signal, the processor 104 may obtain the calibrated environmental sound signal that achieves feedback suppression.

It can be seen that since the reference signal can be directly obtained by the auxiliary calibration microphone which is set at the adjacent side close to the eardrum, the hearing aid device of the present application does not need to pre-store a certain number of frames of an environmental sound signal as a reference signal, and also omits a calibration environment that must be adopted in traditional whistling suppression algorithms or devices. Therefore, the hearing aid device in the present application may work without delay calibration. At the same time, since a requirement for data storage is reduced, a cost of the hearing aid device may also be reduced.

FIG. 2 illustrates a schematic diagram of a hearing aid device 200 when worn in an ear canal according to another embodiment of the present application.

As shown in FIG. 2, a hearing aid device 200 is at least partially disposed in an ear canal, and its sound blocking component 201 is in contact with the ear canal, which divides the ear canal into an adjacent side close to the eardrum and a far side away from the eardrum. A sound propagation channel 213 is formed within the sound blocking component 201, and sound emitted by a receiver 205 is propagated to the eardrum through the sound propagation channel 213. As shown in the figure, an auxiliary calibration microphone 203 is configured to receive sound from the receiver 205 which is propagated along the sound propagation channel 213 on one side of the sound propagation channel 213 such that the auxiliary calibration microphone 203 can quickly and accurately obtain the sound emitted by the receiver 205. Specifically, in the embodiment shown in the figure, a sound insulation component 231 is arranged between the auxiliary calibration microphone 203 and the sound propagation channel 213, which is used to attenuate sound transmission from the sound propagation channel 213 to the auxiliary calibration microphone 203, thereby ensuring that the auxiliary calibration microphone 203 may obtain a auxiliary calibration signal with a more appropriate intensity for a subsequent calibration process.

It should be noted that although the auxiliary calibration microphone 203 shown in the figure is arranged at an opening of one side of the sound propagation channel 213 with a sound insulation component 231 disposed between the auxiliary calibration microphone 203 and the sound propagation channel 213, in other embodiments, the auxiliary calibration microphone 203 can also be arranged at any position suitable for receiving the sound from the receiver 205 which is propagated along the sound propagation channel 213 at one or more sides of the sound propagation channel 213. It should be noted that the “one or more sides” here may be any position at one or more sides of the sound propagation channel which is outside an exit end of sound conduction of the sound propagation channel towards the eardrum. For example, in some embodiments, at least a part of the auxiliary calibration microphone 203 can be constructed as a side wall or part of the sound propagation channel 213. In some other embodiments, the auxiliary calibration microphone 203 can be arranged at a position relatively far away from the sound propagation channel 213, while it is configured to be able to receive the sound transmitted from an opening on a lateral side of the sound propagation channel 213. In some other embodiments, the auxiliary calibration microphone 203 can be arranged to surround the sound propagation channel 213. Certainly, the auxiliary calibration microphone 203 may also be arranged in other ways to obtain a suitable cavity shape effect, which will be illustrated in the following embodiments for details.

Still referring to FIG. 2, the sound blocking component 201 includes an outer blocking part 211 and an inner main body 212. The inner main body 212 is constructed as a shell with a hollow interior, in which one from or all of the environmental sound microphone 202, the auxiliary calibration microphone 203, and the receiver 205 are set. Although not shown in the figure, the inner main body 212 or the outer blocking part 211 can also be set with a processor or other electronic or mechanical components. In the embodiment shown in FIG. 2, at least a part of the environmental sound microphone 202, the auxiliary calibration microphone 203, and the receiver 205 are set in the inner main body 212. Among them, a part of the environmental sound microphone 202 is exposed to the space of the far side away from the eardrum to receive sound of an external environment of the ear canal, generate an environmental sound signal and transmit it to the processor after it is generated. The receiver 205 is set in the inner main body 212 and transmits sound towards the adjacent side close to the eardrum through the sound propagation channel 213 formed in the inner main body 212. The auxiliary calibration microphone 203 is arranged along the sound propagation channel 213 to receive the sound emitted by the receiver 205.

It should be noted that FIG. 2 only exemplarily shows a shape and a structure of the inner main body 212 and the outer blocking part 211, as well as their positions among the environmental sound microphone 202, the auxiliary calibration microphone 203, and the receiver 205. In some embodiments, the environmental sound microphone 202 or the auxiliary calibration microphone 203 may be set on an outer surface of the inner main body 212 or on the outer blocking part 211, for example, be arranged on a side surface of the inner main body 212 or a side surface of the outer blocking part 211. In some other embodiments, the environmental sound microphone 202 may be arranged at a side which is far away from the eardrum but may not be in direct contact with the inner main body 211 or the outer blocking part 212. In some embodiments, the outer blocking part 211 may mainly be formed of a silicone, a sponge or other flexible materials. The structures and functions of other components of the hearing aid device 200 are the same as or similar to those of the hearing aid device 100 shown in FIG. 1, which will not be elaborated here.

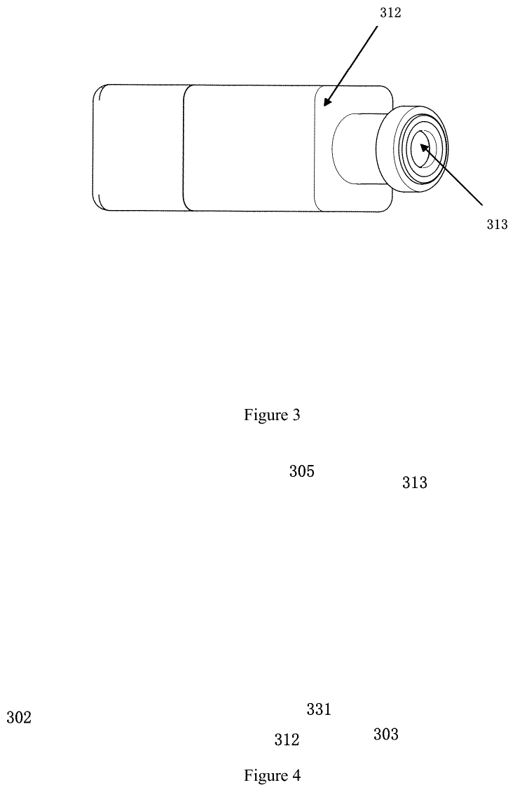

FIG. 3 illustrates a perspective schematic diagram of an inner main body 312 of a hearing aid device according to another embodiment of the present application. A sound propagation channel 313 is formed in the inner main body 312. The position layout of the sound propagation channel 313 and an auxiliary calibration microphone may be similar to the embodiment shown in FIG. 2. Alternatively, a different position layout (for example, a different orientation) may be adopted to achieve a different cavity shape effect, thereby affecting a frequency response of an echo received by the auxiliary calibration microphone. FIGS. 4, 5, and 6 illustrate cross-sectional schematic diagrams of different positions of the auxiliary calibration microphone 302 relative to the sound propagation channel 313, respectively, in the inner main body 312 shown in FIG. 3 according to different embodiments.

As shown in FIG. 4, an environmental sound microphone 302 is disposed on one end of the inner main body 312, which is exposed to the space of the far side away from the eardrum to receive sound of the external environment of the ear canal. Although specific connections are not shown in the figure, the environmental sound microphone 302 and the receiver 305 which is also set in the inner main body 312 may be connected to each other via a wire or wirelessly in order to transmit the environmental sound signal generated by the environmental sound microphone to the receiver 305. Subsequently, the receiver 305 emits sound based on the received environmental sound signal, and the sound is transmitted to the eardrum along the sound propagation channel 313 in a direction illustrated by an arrow in the figure. It should be noted that the direction of the arrow in the figure only exemplarily indicates the main direction of the sound transmitted to the eardrum through the sound propagation channel 313. Still referring to FIG. 4, an auxiliary calibration microphone 303 is set in the inner main body 312, which is configured for receiving sound from the receiver 305 which is propagated along the sound propagation channel 313 on one side of the sound propagation channel 313. Therefore, the auxiliary calibration microphone 303 can quickly and accurately obtain the sound emitted by the receiver 305. Specifically, the auxiliary calibration microphone 303 is disposed in such a way that an orientation of its sound receiving part is generally perpendicular to a sound propagation direction towards the eardrum in the sound propagation channel 313. In some embodiments, a sound insulation component is also arranged between the sound receiving part of the auxiliary calibration microphone 303 and the sound propagation channel 313, which is used to attenuate sound transmission from the sound propagation channel 313 to the auxiliary calibration microphone 303, thereby ensuring that the auxiliary calibration microphone 303 can obtain an auxiliary calibration signal with a more appropriate intensity for a subsequent calibration process.

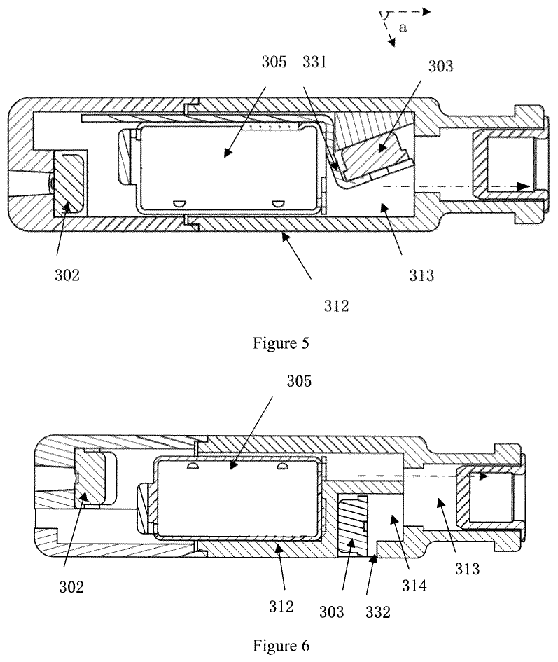

FIG. 5 and FIG. 6 illustrate another two types of position layouts of the auxiliary calibration microphone 302 and the sound propagation channel 313 in the inner main body 312 shown in FIG. 3. Specifically, as shown in FIG. 5, an angle “a” between an orientation of the sound receiving part of the auxiliary calibration microphone 302 and the sound propagation direction towards the eardrum in the sound propagation channel 313 is less than 90 degrees. In some embodiments, the angle “a” is preferably 45 to 60 degrees to obtain a better cavity shape effect. It should be noted that in some embodiments, the angle “a” can also be configured to be greater than 90 degrees. As shown in FIG. 6, the inner main body 312 also includes a cavity 314, which is arranged substantially parallel to the sound propagation channel 313. The cavity 314 is configured to receive the sound transmitted in the sound propagation channel 313. As shown in the figure, an orientation of the sound receiving part of the auxiliary calibration microphone 302 arranged in the cavity 314 may be substantially the same as the sound propagation direction in the sound propagation channel 313. In addition, in some embodiments, the cavity 314 may further include an opening 332 connected with the external space such that the cavity 314 may transmit the sound propagated from the sound propagation channel 314 to the outside of the cavity.

It should be noted that although all of the auxiliary calibration microphones are arranged or configured to receive the sound transmitted in the sound propagation channel formed in the sound blocking component or in the inner main body in the embodiments illustrated in the above figures, in some embodiments, the auxiliary calibration microphone may also be arranged to receive the sound emitted from a sound propagation opening of the sound propagation channel for sound propagation towards the eardrum, thereby obtaining a reverberation signal in the ear canal. For example, in some embodiments, the auxiliary calibration microphone can be set at a position adjacent to the eardrum, and specifically in some embodiments, the auxiliary calibration microphone may be arranged such that the sound receiving part of the auxiliary calibration microphone is oriented towards the eardrum.

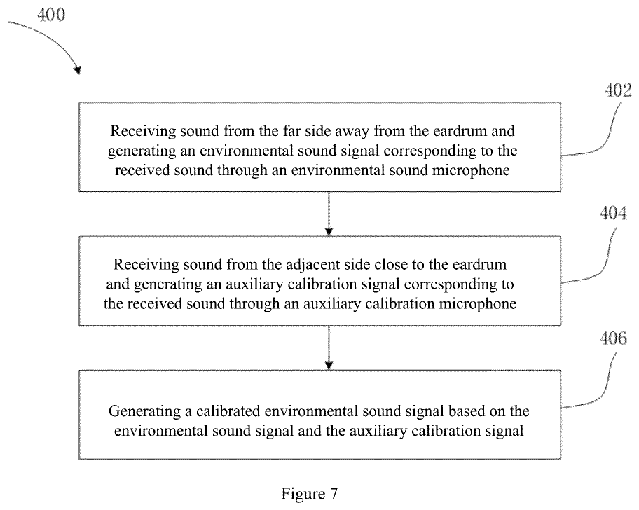

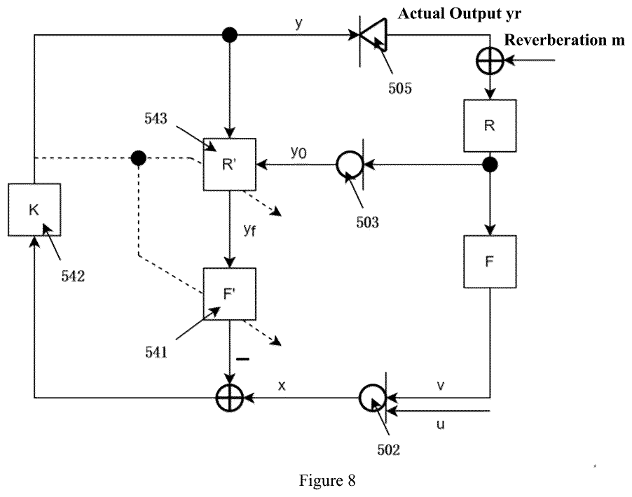

FIG. 7 illustrates a flow chart of a method 400 for implementing sound feedback suppression according to another embodiment of the present application. The method 400 may be used in the hearing aid device 100 shown in FIG. 1, in the hearing aid device 200 shown in FIG. 2, or in the hearing aid device adopting the inner body structure 312 shown in FIG. 3. In the following, the method 400 will be explained in detail in conjunction with the hearing aid device 100 shown in FIG. 1.

As shown in FIG. 7, in step 402, sound from the far side away from the eardrum is received through the environmental sound microphone 102, and an environmental sound signal corresponding to the received sound is generated. In step 404, sound from the adjacent side close to the eardrum is received through the auxiliary calibration microphone 103, and an auxiliary calibration signal corresponding to the received sound is generated. In step 406, the processor 104 generates a calibrated environmental sound signal based on the environmental sound signal and the auxiliary calibration signal.

As mentioned above, the calibrated environmental sound signal is the environmental sound signal after the suppression of the echo feedback, which is the signal expected to be further amplified. In some embodiments, the calibrated environmental sound signal is further processed (for example, amplified) by the processor and then be provided to the receiver 105, which is converted by the receiver 105 into sound required by the user. It should be noted that the processor 104 may adopt any suitable method to obtain the calibrated environmental sound signal based on the environmental sound signal and the auxiliary calibration signal. In some embodiments, the processor 104 may include, for example, a self-adaptive filter. The self-adaptive filter may receive the auxiliary calibration signal as a reference signal to update the coefficient of the self-adaptive filter. Subsequently, based on the updated coefficient of the adaptive filter, the self-adaptive filter may obtain the estimated sound feedback signal which is the echo feedback propagated from the receiver 105 to the environmental sound microphone 102 through the sound feedback path shown in FIG. 1. Subsequently, the processor 104 may generate the calibrated environmental sound signal by subtracting the estimated sound feedback signal from the environmental sound signal.

FIG. 8 illustrates a schematic diagram of a feedback suppression algorithm used in a hearing aid device according to an embodiment of the present application.

As shown in FIG. 8, an environmental sound signal is represented as x, which includes an echo feedback v through a sound feedback path and external environmental sound u. Therefore, when in digital format, the n^{th} frame of the environmental sound signal x[n] collected by an environmental sound microphone may be represented by the following equation (1):

$$x [ n ] = v [ n ] + u [ n ] \qquad ( 1 )$$

where v[n] is the n^{th} frame of the feedback echo through the sound feedback path, u[n] is the n^{th} frame of the external environmental sound, and n is a positive integer.

Still referring to FIG. 8, an auxiliary calibration signal collected by an auxiliary calibration microphone 503 is represented by y₀, and the n^{th} frame of the auxiliary calibration signal y₀[n] collected by the auxiliary microphone 503 may be represented by the following equation (2):

$${y}_{0} [ n ] = R ( {y}_{r} [ n ] + m [ n ] ) \qquad ( 2 )$$

In equation (2), an actual output of the receiver 505 is yᵣ, yᵣ[n] represents the actual output of a receiver 505 in the n^{th} frame, and m[n] represents the n^{th} frame of reverberation in the ear canal. The n^{th} frame of the reverberation and the actual output of sound may be collected by an auxiliary calibration microphone 502 through a filter R, where R is the filter coefficient.

The nₜₕ frame of the actual output yᵣ[n] of the receiver 505 in equation (2) refers to the actual signal generated after the n^{th} frame of the digital signal y[n] received by the receiver 505 is played by the receiver 505. Since the frequency response S of the receiver 505 is known in advance, thereby yᵣ[n] may be calculated based on y[n], and the specific equation is shown as equation (3):

$${y}_{r} [ n ] = Sy [ n ] \qquad ( 3 )$$

Through equations (2) and (3), the reverberation in the ear canal m can be calculated, an inner shape of the ear canal can be estimated through the reverberation, and then the actual sound received at the eardrum can be calculated, allowing for a more accurate elimination of the echo feedback received at the eardrum.

Through a self-adaptive filter R′ 543 shown in FIG. 8, the n^{th} frame of a feedback source signal yᵣ[n] can be estimated by the following equation (4) based on the n^{th} frame of the auxiliary calibration signal y₀[n] and the n−1^{th} frame of the output signal y[n−1]:

$${y}_{f} [ n ] = R ' ( {y}_{0} [ n ] + y [ n - 1 ] ) \qquad ( 4 )$$

where R′ is the coefficient of the self-adaptive filter, and the coefficient of the self-adaptive filter can be calculated by the following equation (5):

$$R ' [ n + 1 ] = R ' [ n ] + μ ⋆ y [ n - 1 ] ⋆ ( y [ n - 1 ] + {y}_{0} [ n ] ) \qquad ( 5 )$$

where R′[n] is the n^{th} iteration of the coefficient of the self-adaptive filter, R′[n+1] is the n+1^{th} iteration of the coefficient of the self-adaptive filter, and μ is the step factor for each iteration.

With a self-adaptive filter F′ 541 shown in FIG. 8, a calibrated environmental sound signal which is amplified through an amplifier is represented as y, and the n^{th} frame of the calibrated environmental sound signal y[n] can be represented by the following equation (6):

$$y [ n ] = K ⋆ error [ n ] = K ( x [ n ] - F ' [ n ] ⋆ {y}_{f} [ n ] ) \qquad ( 6 )$$

where error[n] is the calibrated n^{th} frame of the environmental sound signal, K is the amplification coefficient of the amplifier 542, F′ is the coefficient of the self-adaptive filter, and the coefficient of the self-adaptive filter can be represented by the following equation (7):

$$F ' [ n + 1 ] = F ' [ n ] + μ ⋆ yf [ n ] ⋆ y [ n ] \qquad ( 7 )$$

wherein F′[n] is the n^{th} iteration of the coefficient of the self-adaptive filter, F′[n+1] is the n+1^{th} iteration of the coefficient of the self-adaptive filter, and μ is the step factor for each iteration.

It can be seen that by applying the algorithm above, the feedback signal is effectively eliminated in the actual sound output yᵣ which is generated by the receiver, thereby improving the user experience. In some embodiments, an update of the coefficient of the above self-adaptive filter may be calculated using a stochastic gradient algorithm, including least mean square (LMS) algorithm or normalized least mean square (NLMS) algorithm. It can be understood that other self-adaptive filtering algorithms may also be applied to the self-adaptive filter used in the embodiments of the present application.

In some embodiments, since the signal collected by the auxiliary calibration microphone includes an actual sound source received by the eardrum, the signal can be used to estimate the signal received by the eardrum, which helps to provide accurate gain for the user.

In some embodiments, apart from the environmental sound microphone, the hearing aid device may further include a second environmental sound microphone in a position far away from the ear canal. The second environmental sound microphone is configured to receive sound from the far side away from the eardrum and generate a second environmental sound signal corresponding to the received sound. In some embodiments, the second environmental sound microphone can be a microphone configured for being arranged at an ear dorsum, or other microphones arranged outside the ear canal. In this hearing aid device, the processor may be further configured to receive the second environmental sound signal and generate a calibrated environmental sound signal based on a combination of the environmental sound signal, the auxiliary calibration signal, and the second environmental sound signal. When this hearing aid device is worn by a user, the impact of the feedback echo on the second environmental sound microphone is almost negligible compared to the environmental sound microphone near the ear canal because of the second environmental sound microphone being far away from the ear canal (for example, arranged at the ear dorsum). Therefore, the second environmental sound signal may be used to predict the actual input of the first environmental sound microphone, and the estimated value is used to update the coefficient of the self-adaptive filter, thereby maintaining the stability of the whistling suppression algorithm.

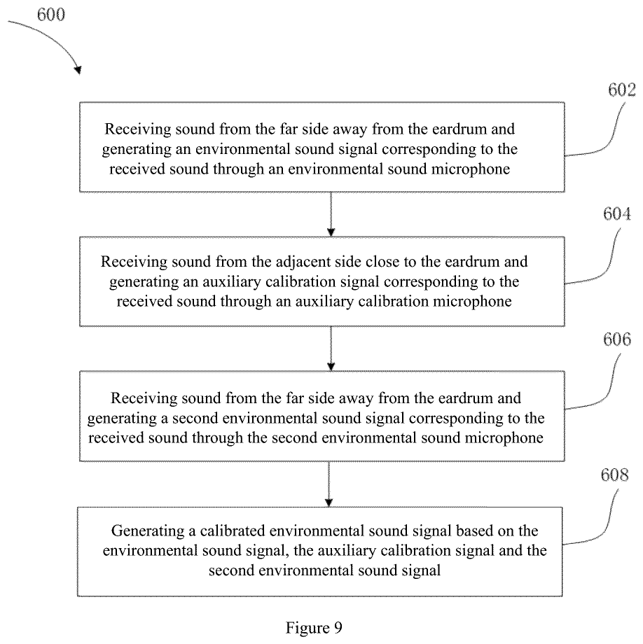

FIG. 9 illustrates a flow chart of a sound feedback suppression method 600 using a hearing aid device which further includes a second environmental sound microphone.

As shown in FIG. 9, step 602 and step 604 of the method 600 are substantially the same as step 402 and step 404 of the method 400 illustrated in FIG. 7, which will not be elaborated here. In step 606, the method 600 further includes receiving sound from the far side away from the eardrum through the second environmental sound microphone and generating a second environmental sound signal corresponding to the received sound. Subsequently, in step 608, the hearing aid device may generate a calibrated environmental sound signal based on the environmental sound signal, the auxiliary calibration signal, and the second environmental sound signal.

In the method 600 shown in FIG. 9, a processor may adopt any suitable way to determine the calibrated environmental sound signal for feedback suppression based on a combination of the environmental sound signal, the auxiliary calibration signal, and the second environmental sound signal. In some embodiments, similar to the description of the embodiment of the method 400 shown in FIG. 7, the processor may include an self-adaptive filter, which receives the auxiliary calibration signal and the second environmental sound signal as reference signals for the update of the coefficient of the self-adaptive filter, and obtains the estimated sound feedback signal of the sound feedback propagated from the receiver to the environmental sound microphone through the sound feedback path based on the updated coefficient of the self-adaptive filter. Subsequently, the calibrated environmental sound signal can be obtained by subtracting the estimated sound feedback signal from the environmental sound signal. Specifically, in some embodiments, the processor further includes a second self-adaptive filter. The second environmental sound signal is filtered by the second self-adaptive filter and used as a reference signal for the update of the coefficient of the self-adaptive filter. Subsequently, based on the updated coefficient of the self-adaptive filter, an actual input estimation signal of the actual input propagated to the environmental sound microphone through the sound propagation path can be obtained, and the actual input estimation signal is used to update the coefficient of the self-adaptive filter.

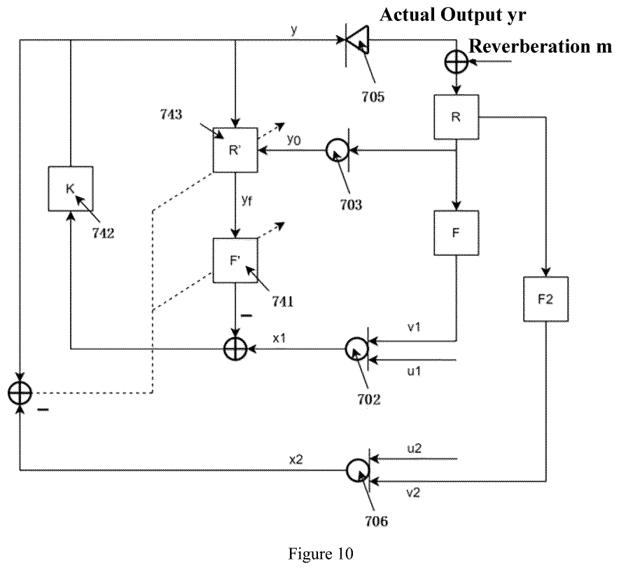

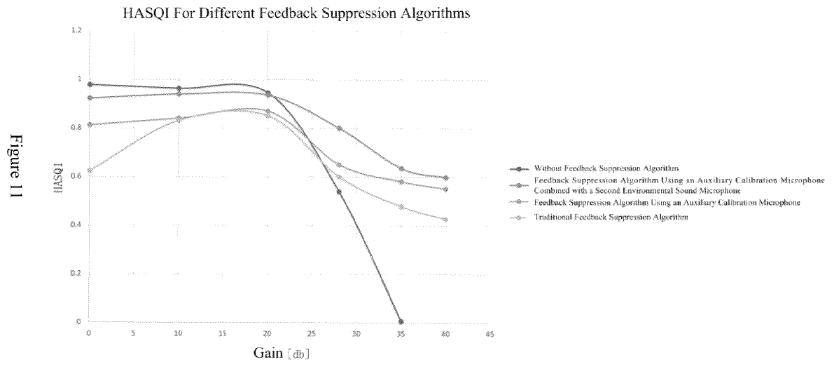

FIG. 10 illustrates a schematic diagram of a feedback suppression algorithm used in a hearing aid device according to another embodiment of the present application.

As shown in FIG. 10, signals collected by an environmental sound microphone, an auxiliary calibration microphone, and a receiver are similar to the embodiment shown in FIG. 8, which will not be elaborated here. The following only illustrates differences between the embodiment shown in FIG. 10 and the embodiment shown in FIG. 8.

The signal collected by the second environmental sound signal is represented as x2, which includes an echo feedback v2 through the sound feedback path and external environmental sound u2. Therefore, an equation of the n^{th} frame of an environmental sound signal x2[n] collected by a second environmental sound microphone 706 is represented as following:

$$x 2 [ n ] = v 2 [ n ] + u 2 [ n ] \qquad ( 8 )$$

where v2[n] is the feedback echo through the sound feedback path, and u2[n] is the external environmental sound.

The environmental sound signal x2 collected by the second environmental sound microphone 706 can be used to predict u1 and be used to update the coefficient of the filter, which helps to remove the impact of the external environmental sound on the estimation of the feedback path. Equations of the update of the coefficients of the related filters are represented as following:

$$F ' [ n + 1 ] = F ' [ n ] + μ ⋆ {y}_{f} [ n ] ⋆ ( y [ n ] - x 2 [ n ] ) \qquad ( 9 )$$

$$R ' [ n + 1 ] = R ' [ n ] + μ ⋆ {x}_{2} [ n ] ⋆ ( y [ n ] - x 2 [ n ] ) \qquad ( 10 )$$

where R′[n] and F′[n] are the n^{th} iteration of the coefficients of the self-adaptive filters, R′[n+1] and F′[n+1] are the n+1^{th} iteration of the coefficients of the self-adaptive filters, and u is the step factor for each iteration. In some embodiments, the update of the above self-adaptive filters can be calculated using a stochastic gradient algorithm, including least mean square (LMS) algorithm or normalized least mean square (NLMS) algorithm.

FIG. 11 illustrates a graph of HASQI (Hearing-Aid Speech Quality Index) with the change of gain levels without using a feedback suppression algorithm, using a feedback suppression algorithm of embodiments of the present application, and using a traditional feedback suppression algorithm. The “traditional feedback suppression algorithm” shown in the figure refers to the feedback suppression algorithm that stores a certain number of frames of an environmental sound signal as a reference signal as mentioned earlier.

As shown in FIG. 11, in comparison to the traditional feedback suppression algorithm, the feedback suppression algorithm using an auxiliary calibration microphone and the feedback suppression algorithm using an auxiliary calibration microphone combined with a second environmental sound microphone both demonstrate better HASQI levels at any gain level. Under circumstance of relatively high gain, the two algorithms described herein both demonstrate better and more stable HASQI levels compared to those cases without using a feedback suppression algorithm and using a feedback suppression algorithm.

Although the number of the environmental sound microphones and the number of the auxiliary calibration microphones in the embodiments illustrated in the above figures is one, in some other embodiments, the number of the environmental sound microphones and the number of the auxiliary calibration microphones may be any number. In some embodiments, the hearing aid device includes multiple environmental sound microphones for collecting sound from the far side away from the eardrum to further improve the effect of the whistling suppression. Furthermore, in addition to the structures shown in the figures, the hearing aid device of the present application may also include other components or elements, such as power components, storage components, or antennas set at the ear dorsum, and so on.

The embodiments of the present invention may be implemented through hardware, software, or a combination of software and hardware. The hardware may be implemented using a specialized logic; the software may be stored in a memory and be executed by an appropriate instruction execution system, such as a microprocessor or a hardware with a specialized design. Those skilled in the art may understand that the devices and the methods described above may be implemented by using executable instructions in a computer and/or being included in control code in a processor, such as code provided on a carrier medium such as a disk, CD or DVD ROM, a programmable memory such as a read-only memory (firmware), or a data carrier such as an optical or electronic signal carrier. The devices and the modules of the present invention may be implemented by a hardware circuit such as an extra-large scale integrated circuit or gate array, a semiconductor device such as a logic chip and a transistor, or a programmable hardware device such as a field programmable gate array and a programmable logic device, etc. The devices and the modules of the present invention may also be implemented by software which may be executed by various types of processors, or may be implemented by a combination of the hardware circuit and the software mentioned above, for example, firmware.

While several modules or sub-modules of the system are mentioned in the detailed description above, this division is exemplary only and not mandatory. In fact, according to the embodiments of the present application, the features and the functions of two or more modules described above may be embodied in one module. Conversely, the features and the functions of one module described above may be further divided into multiple modules for the embodiment.

Those skilled in the art can understand and implement variations to the disclosed embodiments by referring to the specification, the disclosed content, the drawings, and the attached claims. In the claims, the term “comprising” does not exclude other elements and steps, and the terms “a” and “an” do not exclude plurality. In the actual application of the present application, a component may perform the functions of multiple technical features cited in the claims. Any reference label in the claims should not be understood as a limitation of the scope.

1. A hearing aid device at least partially disposed in an ear canal, the hearing aid device comprising:
a sound blocking component constructed to be in contact with the ear canal to divide the ear canal into a far side away from an eardrum and an adjacent side close to the eardrum and block sound transmission between the far side away from the eardrum and the adjacent side close to the eardrum;
an environmental sound microphone configured for receiving sound from the far side away from the eardrum and generating an environmental sound signal corresponding to the received sound;
an auxiliary calibration microphone configured for receiving sound from the adjacent side close to the eardrum and generating an auxiliary calibration signal corresponding to the received sound;
a processor configured to receive the environmental sound signal and the auxiliary calibration signal and generate a calibrated environmental sound signal based on the environmental sound signal and the auxiliary calibration signal; and
a receiver configured to receive the calibrated environmental sound signal from the processor and convert the calibrated environmental sound signal into sound emitted to the adjacent side close to the eardrum.

2. The hearing aid device of claim 1, wherein the processor comprises a self-adaptive filter, and generating a calibrated environmental sound signal based on the environmental sound signal and the auxiliary calibration signal comprises:
correcting the auxiliary calibration signal through the self-adaptive filter to obtain an estimated sound feedback signal of an echo feedback propagated from the receiver to the environmental sound microphone;
subtracting the estimated sound feedback signal from the environmental sound signal to obtain the calibrated environmental sound signal.

3. The hearing aid device of claim 1 or 2, wherein the processor comprises a signal amplifier, and the signal amplifier amplifies the calibrated environmental sound signal and sends the calibrated environmental sound signal to the receiver.

4. The hearing aid device of claim 2, wherein the self-adaptive filter applies least mean square algorithm or normalized least mean square algorithm.

5. The hearing aid device of claim 1, wherein the sound blocking component comprises a sound propagation channel for transmitting sound from the receiver to the eardrum, and the auxiliary calibration microphone is arranged to receive the sound propagated in the sound propagation channel from the receiver at least from one side of the sound propagation channel.

6. The hearing aid device of claim 5, wherein a sound insulation component is arranged between the auxiliary calibration microphone and the sound propagation channel, and the sound insulation component is arranged to attenuate the sound transmission from the sound propagation channel to the auxiliary calibration microphone.

7. The hearing aid device of claim 5, wherein at least a part of the auxiliary calibration microphone constitutes a sidewall of the sound propagation channel.

8. The hearing aid device of claim 5, wherein an angle between an orientation of a sound receiving part of the auxiliary calibration microphone and a sound propagation direction towards the eardrum in the sound propagation channel is approximately 90 degrees.

9. The hearing aid device of claim 5, wherein an angle between an orientation of a sound receiving part of the auxiliary calibration microphone and a sound propagation direction towards the eardrum in the sound propagation channel is less than 90 degrees.

10. The hearing aid device of claim 5, wherein the hearing aid device further comprises a cavity substantially parallel to the sound propagation channel, the cavity is constructed to receive sound in the sound propagation channel, the auxiliary calibration microphone is arranged in the cavity, and an orientation of an sound receiving part of the auxiliary calibration microphone is substantially the same as a sound propagation direction towards the eardrum in the sound propagation channel.

11. The hearing aid device of claim 10, wherein the cavity is further constructed to transmit sound propagated from the sound propagation channel to outside of the cavity.

12. The hearing aid device of claim 1, wherein the sound blocking component comprises a sound propagation channel for transmitting sound from the receiver to the eardrum, the sound propagation channel has a sound propagation opening for transmitting sound towards the eardrum, and the auxiliary calibration microphone is arranged to receive sound emitted from the sound propagation opening.

13. The hearing aid device of claim 1, wherein the environmental sound microphone is set such that when the hearing aid device is at least partially disposed in the ear canal, the environmental sound microphone is disposed at an entrance of the ear canal or in the ear canal.

14. The hearing aid device of claim 1, wherein the auxiliary calibration microphone is configured to be adjacent to the receiver.

15. The hearing aid device of claim 5, wherein the sound blocking component comprises an inner main body and an outer blocking part arranged substantially around the inner main body, and the sound propagation channel is formed within the inner main body.

16. The hearing aid device of claim 1, wherein the receiver is a moving iron receiver.

17. The hearing aid device of claim 1, wherein the hearing aid device further comprises a second environmental sound microphone, the second environmental sound microphone is set such that when the hearing aid device is at least partially disposed in the ear canal, the environmental sound microphone is in a position far away from the ear canal to receive sound from the far side away from the eardrum and generate a second environmental sound signal corresponding to the received sound.

18. The hearing aid device of claim 17, wherein the second environmental sound microphone is configured for being arranged at an ear dorsum.

19. The hearing aid device of claim 17, wherein the processor is further configured to receive the second environmental sound signal and generate a calibrated environmental sound signal based on the environmental sound signal, the auxiliary calibration signal, and the second environmental sound signal.

20. A method for achieving sound feedback suppression using a hearing aid device at least partially disposed in an ear canal, wherein the hearing aid device comprises a sound blocking component, the sound blocking component is constructed to be in contact with the ear canal to divide the ear canal into a far side away from an eardrum and an adjacent side close to the eardrum and block sound transmission between the far side away from the eardrum and the adjacent side close to the eardrum, and wherein the method comprises:
receiving sound from the far side away from the eardrum and generating an environmental sound signal corresponding to the received sound through an environmental sound microphone;
receiving sound from the adjacent side close to the eardrum and generating an auxiliary calibration signal corresponding to the received sound through an auxiliary calibration microphone;
generating a calibrated environmental sound signal based on the environmental sound signal and the auxiliary calibration signal.

21. The method of claim 20, wherein generating the calibrated environmental sound signal based on the environmental sound signal and the auxiliary calibration signal comprises:
correcting the auxiliary calibration signal through a self-adaptive filter of the hearing aid device to obtain an estimated sound feedback signal of an echo feedback propagated from the receiver of the hearing aid device to the environmental sound microphone;
subtracting the estimated sound feedback signal from the environmental sound signal to obtain the calibrated environmental sound signal.

22. The method of claim 20, wherein the hearing aid device further comprises a second environmental sound microphone, the second environmental sound microphone is set such that when the hearing aid device is at least partially disposed in the ear canal, the environmental sound microphone is in a position far from the ear canal, the method further comprises:
receiving sound from the far side away from the eardrum and generating a second environmental sound signal corresponding to the received sound through the second environmental sound microphone;
generating a calibrated environmental sound signal based on the environmental sound signal, the auxiliary calibration signal and the second environmental sound signal.
